(19) United States
(12) Patent Application Publication
(10) Pub. No.: US 2026/0223608 A1
(43) Pub. Date: Jul. 30, 2026

(54) METHODS FOR DEPOSITING A LAYER INCLUDING GROUP III AND GROUP V ELEMENTS ON A SILICON SUBSTRATE

(71) Applicant: AIXTRON SE, Herzogenrath (DE)

(72) Inventors: Christof MAUDER, Aachen (DE); Dirk FAHLE, Wegberg (DE); Ian Don BOOKER, Aachen (DE); Utz Herwig HAHN, Raeren (BE)

(21) Appl. No.: 19/142,356

(22) PCT Filed: Dec. 18, 2023
(86) PCT No.: PCT/EP2023/086383

§ 371 Date: Jun. 23, 2025

(30) Foreign Application Priority Data
Dec. 28, 2022 (DE) 10 2022 134 874.1

(51) Int. Cl. H10P 14/60; C23C 16/02; C23C 16/44; C23C 16/455; H10P 14/69; H10P 14/694

(52) U.S. Cl. CPC H10P 14/6302; C23C 16/0272; C23C 16/4405; C23C 16/4408; C23C 16/45523; H10P 14/6334; H10P 14/6905; H10P 14/69472

(57) ABSTRACT

A method for depositing a layer including elements of main groups III and V on a silicon carbide (SiC) surface of a silicon substrate in a process chamber of a chemical vapor deposition (CVD) reactor. The SiC surface is formed by a first chemical reaction between a first gaseous starting material containing carbon and the surface of the silicon substrate at a first elevated temperature. Subsequently, the III-V layer is formed on the SiC surface by a second chemical reaction between a second gaseous starting material containing a main group III element with a third gaseous starting material containing a main group V element at a second elevated temperature.

### FIELD OF THE TECHNOLOGY

The invention relates to a method for the deposition of a layer consisting of elements of the III. and V. main groups on an SiC surface of a substrate made of silicon in a process chamber of a CVD reactor, wherein the SiC surface is produced by a first chemical reaction of a carbon-containing gaseous first starting material with the surface of the Si substrate at a first elevated temperature of the substrate, and the layer is produced by a second chemical reaction of a second gaseous starting material containing the element of the III. main group, and a third gaseous starting material containing the element of the V. main group at a second elevated temperature.

### PRIOR ART

US 2005/0263754 A1 discloses a method for the deposition of AlN or GaN on an Si substrate, whereby the substrate has an opening open at the top, which gives the substrate a high level of roughness. At temperatures between 800° C. and 1,400° C., propane, methane, or butane is fed into a process chamber, in which the substrate to be coated is located, in order to carbonize the surface. Here the aim is to form an SiC layer with a thickness of at least 0.1 nanometers and a maximum of 100 nanometers, onto which the III-V layer is then deposited.

US 2004/0029365 A1 discloses a method for the deposition of gallium nitrite on a silicon substrate, in which the surface is first transformed into SiC by the infeed of a hydrocarbon, for example ethylene. SiC is then epitaxially deposited on the latter. The III-V layer is deposited onto this SiC layer.

EP 1 842 941 B1 or EP 1 842 940 A1 describe a method in which an Si substrate is placed in a reactor and heated up to an elevated temperature. The substrate is first treated with hydrogen at a temperature of 1,100° C. so as to produce an H-terminated surface. At the same temperature, a low mass flow rate of TMAl is fed into the process chamber. A decomposition of the TMAl into AlCH takes place on the substrate, whereby a methyl residue remains. The methyl residue decomposes into carbon and hydrogen. The carbon combines with silicon atoms of the substrate to form a monomolecular layer of SiC on the surface. The remaining aluminum can diffuse into the substrate. There it can produce an AlSi alloy. However, it can also remain on the surface, and can have a catalytic effect when a subsequent III-V layer is deposited. The III-V layer deposited here is GaN with an increased TMAl flow rate and the simultaneous injection of ammonia.

US 2010/0273291 A1 describes an MOCVD method for the deposition of GaN layers, whereby prior to the deposition process the process chamber is cleaned with HCl in the absence of substrates.

EP 3 503 163 A1 describes a method for the deposition of indium-containing layers on an Si substrate, whereby the substrate, which has previously been heated to an elevated temperature of between 1,000° C. and 1,100° C., is exposed to a low flow rate of an indium-containing organic compound, such that an SiC layer forms on the surface of the substrate.

The methods described in the above-cited US 2005/0263754 A1 and US 2004/0029365 A1 produce layers of inadequate surface quality. With the variants described in the above-cited EP 1 842 941 B1 and EP 3 503 163 A1, in which a metal-containing starting material is used to form the SiC layer, the layer quality can be improved. In these variants, however, there is a risk that the metal atoms remaining on the surface, or diffusing into the substrate, will have a negative effect on the electronic properties of the III-V layer, in particular if the latter is a nitrogen-containing layer.

The problem with all the methods described above is that metal atoms can be incorporated into the silicon substrate if the deposition method is repeated, in particular if it is repeated a number of times.

In the prior art, it is also of known art to pre-treat the silicon substrate at a relatively low temperature<150° Celsius by the infeed of an organometallic compound of an element of the III. main group, for example aluminum.

### SUMMARY OF THE INVENTION

The invention is based on the object of improving the above-cited method in such a way that the disadvantages described above are eliminated.

The object is achieved by the technical instruction specified in the claims, whereby the subsidiary claims are not only developments of the method specified in claim 1, but are also independent solutions to the object.

The object is achieved by a method with the following method steps:
a. Provision of a CVD reactor with a gas inlet element for the infeed of reactive gases into a process chamber of the CVD reactor, whereby the CVD reactor has a heater, with which a susceptor can be brought to an elevated temperature, and a gas outlet element, with which decomposition products of the process gas can be led out of the process chamber;
b. Provision of a cleaning gas, which has the property of reacting chemically at a cleaning temperature with metallic residues on surfaces of the process chamber, so as to form a gas containing the metallic residues;
c. Provision of a carbon-containing reactive gas that does not contain any metal;
d. Provision of a first gaseous starting material, which contains an element of the III. main group, and a second gaseous starting material, which contains an element of the V. main group;
e. Tempering of the surfaces of the process chamber up to a cleaning temperature;
f. Infeed of the cleaning gas into the process chamber, and removal of the metallic residues by the formation of the gas containing the metallic residues, and the removal of this gas through the gas outlet element;
g. Purging of the process chamber with an inert gas;
h. Loading of the susceptor with at least one silicon substrate;
i. Tempering of the substrate up to a first elevated temperature;
j. Production of an SiC surface that is as closed as possible by the infeed of the carbon-containing reactive gas into the process chamber, and the execution of a chemical reaction of the carbon-containing gas with the Si surface of the substrate;
k. Tempering of the substrate up to a second elevated temperature;
l. Deposition of a III-V layer onto the SiC surface by the infeed of the first and second gaseous starting materials into the process chamber.

What are essential here, in the first instance, are the method steps b, e and f, which are executed without the presence of a substrate, and which ensure that by the infeed of a cleaning gas into the process chamber, no metallic residues from previous processes remain on the surfaces. It is also essential that method steps j to 1 are executed in immediate succession. For this purpose, it is particularly advantageous if the first elevated temperature corresponds to the second temperature. The deposition of the III-V layer (step 1) then takes place immediately after the production of the SiC surface (step j). All steps are executed in the same process chamber.

Before the substrate is actually coated with a III-V layer, a cleaning method is used to remove parasitic coatings from the surfaces of the process chamber that have formed there during a previous coating process. These layers contain gallium. The silicon substrate can only be introduced into the process chamber once these surfaces have been made metal-free, that is to say, no longer contain gallium. This can take the form of a pre-treated silicon substrate, from which the native oxides have been removed by pre-treatment at an elevated temperature in a hydrogen atmosphere. This pre-treatment of the substrate can take place in a different process chamber. However, it can also take place in the same process chamber. For example, after the cleaning step, and before the SiC surface is produced, hydrogen can be infed into the process chamber at an elevated temperature. This preferably takes place in the presence of the substrate, so that oxides can be removed from the surface of the substrate by a reaction with the hydrogen. The at least one silicon substrate can have a diameter of at least 150 mm. The thickness of the substrate is less than 1.2 mm. A substrate with a diameter of 300 mm can have a thickness of 1.5 mm. The thickness of the substrate can therefore lie between 1 mm and 2 mm. The substrates that can be used are polished silicon substrates that have smooth surfaces, on which a layered structure comprising a plurality of layers can be deposited. The carbon-containing reactive gas can be a hydrocarbon. It can be methane, ethane, propane, butane, ethylene, etc. It can take the form of alkanes, alkenes or alkynes. The gaseous starting materials of the III. and V. main groups can be organometallic compounds of the III. main group and hydrides of the V. main group. The element of the III. main group is preferably aluminum or gallium, and the element of the V. main group is preferably nitrogen. The method enables, in particular, the deposition of AlN layers or GaN layers on a silicon substrate, whereby the silicon surface of the substrate is carbonized beforehand. The carbonization is executed in such a way that no reaction takes place between the organometallic starting material and the silicon surface during the deposition of the III-V layer. The SiC layer can be polycrystalline. The cleaning step and the deposition of the III-V layer can take place at a temperature between 950° C. and 1,100° C., at a temperature between 1,000° C. and 1,060° C., or at a temperature between 970° C. and 1,000° C. The temperature at which the silicon surface is carbonized is preferably identical to the temperature at which the III-V layer is deposited. Provision can also be made for the carbon-containing reactive gas to be present in the process chamber for a transition period simultaneously with the reactive gases of the III. and V. main groups. Provision can be made for the molar flow rate of the carbon-containing gas into the process chamber to lie in the range between 0.1% and 0.3% of the total molar flow rate.

After the deposition of the III-V layer, or after the deposition of further layers onto this first III-V layer, the process chamber can be brought into a dischargeable state. After the unloading of the substrate, the process chamber is closed, and steps e and f are executed. The surfaces of the process chamber that have parasitic coatings, in particular Al or Ga, that is to say, metals, are cleaned during the first deposition of the III-V layer. These metals are removed during this cleaning process. The process chamber can then be reloaded with one or a plurality of substrates, and the coating procedure described above can be repeated, in which the substrate is firstly tempered in order to remove the natural oxides from the silicon substrate, an SiC monolayer is produced, and at least one III-V layer is then deposited.

The cleaning method preceding the loading of the susceptor with the substrate can be executed using the cleaning steps described in DE 10 2013 104 105 A1. In a first cleaning step, which is executed at a high cleaning temperature in the range between 1,000° C. and 1,300° C., it is essentially only hydrogen that is introduced into the process chamber. At a total pressure that can be between 50 mbar and 900 mbar, preferably about 100 mbar, 10 to 100 slm of H₂ is introduced into the process chamber for about 10 to 60 minutes. This converts the GaN deposited on the process chamber walls into NH₃. Any silicon oxide layers that are present are reduced. In a possible second cleaning step, other metal components are removed from the surface. This step takes place at low pressures, in particular, below 100 mbar. The susceptor temperature here lies in a range between 800° C. and 900° C., During this time Cl₂ and N₂ can be fed into the process chamber. In the course of this decomposition step, metals react into volatile chlorides, which can be discharged through the gas outlet element.

The method in accordance with the invention also has an advantage over the method cited earlier, whereby the silicon substrate is pre-treated at a reduced temperature with an organometallic compound, for example an organometallic aluminum compound. This is because, after the removal of the oxide layer from the surface of the silicon substrate at temperatures above 1,000° Celsius, it is not necessary to cool the process chamber to a temperature below 750° Celsius, which is time-consuming. With the inventive method the cycle times can therefore also be reduced.

### BRIEF DESCRIPTION OF THE DRAWING

An example of embodiment of the invention is explained in what follows, with reference to the accompanying drawing.

FIG. 1 shows schematically a CVD reactor.

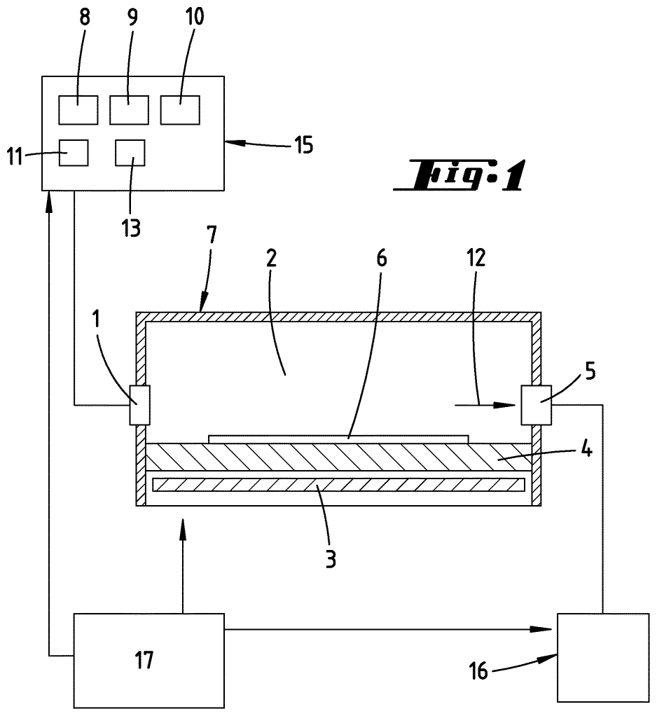

### DESCRIPTION OF THE FORMS OF EMBODIMENT

The CVD reactor 7 has a gas-tight housing. A gas inlet element 1 is located in the housing, with which a process gas 9, 10 provided by a gas supply system 15, which contains various reactive gases, can be infed into a process chamber 2.

In the process chamber 2 is located a susceptor 4, which can be heated to a process temperature from below with a heating device 3. Decomposition products can be led out of the process chamber with a gas outlet element 5. The decomposition products can be led to a gas purification system 16.

A control device 17 is provided, with which the valves and mass flow rate controllers (not shown), by way of which the gases from the gas sources 8, 9, 10, 11, 13 are infed into the process chamber 2, can be controlled.

For purposes of depositing a III-V layer on a silicon substrate, the process chamber 2 is first brought into a processable state, in which any metal residues remaining on the surface of the walls of the process chamber 2 from previous processes are removed in a first cleaning step. This takes place without the presence of a substrate 6 in the process chamber 2. Chlorine or ammonia, or ammonia and then chlorine, can be fed into the process chamber 2.

After purging of the process chamber 2 with an inert gas, and cooling of the process chamber 2, the process chamber 2 is loaded with the silicon substrate. The process chamber 2 is purged and heated. The silicon substrate 6 preferably has a polished surface, but may still have oxides.

Hydrogen is fed into the process chamber, so as to remove oxides from the surface of the substrate. However, this pre-treatment process, that is to say, the removal of oxides from the surface of the silicon substrate, can also be executed in another process chamber, from which the substrate is removed in order to bring it into the cleaned process chamber.

A carbon-containing gas, for example an alkane, is then fed into the process chamber through the gas inlet element 5. The carbon in the carbon-containing gas reacts with the surface of the substrate at a temperature that lies above 970° C., and preferably in the range between 970° C. and 1,000° C., to form a monolayer of SiC. The reaction takes 4 to 10 seconds. The flow rate of the carbon-containing gas is more than 66 sccm. This results in a saturation of the substrate surface. With a total hydrogen flow rate of the order of 180 slm (that is to say, approximately 8 mol/min), an ethene flow rate should be 0.5 to 50 mmol/min. Here the C₂H₄ concentration in the H₂ should be 0.006-0.6% (60-6,000 ppm) at a pressure in the process chamber of 35-300 mbar.

Immediately afterwards, or while the carbon-containing gas is still being fed into the process chamber, a process gas consisting of an organometallic aluminum compound and ammonia, together with an inert gas, for example hydrogen, nitrogen, or a noble gas, is fed into the process chamber 2 through the gas inlet element 5, such that an AlN layer forms on the SiC monolayer. This can take place at the same temperature.

The process chamber 2 is then purged with an inert gas, or further layers are deposited. In particular, provision is made for one layer of a subsequently deposited layer sequence to contain gallium, and in particular to be a GaN layer.

After completion of the coating step, the process chamber 2 is cooled down, and the substrate 6 is removed from the process chamber 2.

It is considered essential that, before the infeed of a gas containing a metal, in particular a III. main group metal, a conversion of the silicon surface of the substrate takes place, in that a metal-free reactive gas containing carbon is fed into the process chamber, which gas reacts with the silicon surface of the substrate. Furthermore it is considered essential that the heating of the substrate takes place in a metal-free environment, for which purpose it is necessary to clean the environment of the substrate beforehand using a suitable method. The gas supply system 15 can have a cleaning gas source 8, which, for example, stores a chlorine-containing gas, a process gas source 9, which, for example, stores a gallium-containing gas, a further process gas source 10, which contains a nitrogen-containing gas, and a gas source 11, in which the carbon-containing gas is present. The gases are fed by way of a supply line into the process chamber 2, in which the gases react chemically. Reaction products 12 are formed, which are transported through a gas outlet to a gas cleaning system 16.

It is particularly advantageous if on each occasion the same layer sequences are deposited in the process chamber 2 multiple times in succession in an industrial production process, whereby at least one of the layer sequences contains gallium, and gallium is deposited on the surfaces of the process chamber 2 in the course of deposition. The gallium remaining in the process chamber 2 is removed by cleaning the process chamber prior to each deposition process. This prevents gaseous gallium, which could have a corrosive effect on the silicon surface of the substrate, from being generated when the process chamber 2 is heated up in the presence of the substrate 6.

The above statements serve to explain the inventions covered by the application as a whole, which, in each case also independently, develop the prior art, at least by means of the following combinations of features, whereby two, a plurality, or all of these combinations of features may also be combined, namely:

A method for the deposition of a layer consisting of elements of the III. and V. main groups on a substrate of silicon comprising the following steps:
a. Provision of a CVD reactor R with a gas inlet element 1, for the infeed of reactive gases into a process chamber 2 of the CVD reactor, which has a heating device 3 with which a susceptor 4 can be brought to an elevated temperature, and which has a gas outlet element 5 with which decomposition products of the process gas can be led out of the process chamber 2;
b. Provision of a cleaning gas 8, which has the property of reacting chemically at a cleaning temperature with metallic residues on surfaces of the process chamber 2, so as to form a gas containing the metallic residues;
c. Provision of a carbon-containing reactive gas 11 that does not contain any metal;
d. Provision of a first gaseous starting material 9, which contains an element of the III. main group, and a second gaseous starting material 10, which contains an element of the V. main group;
e. Tempering of the process chamber 2, which does not contain a substrate and has metallic residues on its surfaces, up to a cleaning temperature TR;
f. Infeed of the cleaning gas 8 into the process chamber 2, and removal of the metallic residues by the formation of the gas 12 containing the metallic residues, and the removal of this gas through the gas outlet element 4;
g. Purging of the process chamber 2 with an inert gas 13;
h. Loading of the susceptor 4 with at least one silicon substrate 6;
i. Tempering of the substrate up to a first elevated temperature T1;
j. Production of an SiC surface by the infeed of the carbon-containing reactive gas 11 into the process chamber 2, and by execution of a chemical reaction of the carbon-containing gas 11 with the Si surface of the substrate 6;
k. Tempering of the substrate up to a second elevated temperature T2;
l. Deposition of a III-V layer onto the SiC surface by the infeed of the first and second gaseous starting materials 9, 10 into the process chamber 2;
   whereby all steps in the same process chamber 2 are executed in succession, and steps j, k, l are executed in immediate succession.

A method, which is characterized in that, before the production of the SiC surface (step j), hydrogen is fed into another, or the same, process chamber 2, in which the substrate 6 is located, and this process chamber 2, which then contains hydrogen, is heated up to a third elevated temperature T3.

A method, which is characterized in that the first reactive starting material 9 is an organometallic compound, or an organometallic gallium compound, or an aluminum compound, and in that the second reactive starting material 10 is a hydride or NH₃.

A method, which is characterized in that the carbon-containing reactive gas 11 is a hydrocarbon, or is C₂H₄.

A method, which is characterized in that the cleaning gas 8 contains ammonia or a halogen, and the cleaning temperature lies between 1,000° C. and 1,300° C.

A method, which is characterized in that the SiC surface is produced at the first temperature T1 between 950° C. and 1,050° C., or between 970° C. and 1,000° C., and the infeed of the carbon-containing reactive gas continues until the Si surface of the substrate is completely saturated with SiC, or wherein the duration of the infeed is at least 2 seconds, or 4 to 10 seconds.

A method, which is characterized in that the deposition of the III-V layer takes place at a temperature between 1,000° C. and 1,060° C.

A method, which is characterized in that the second elevated temperature T2 corresponds to the first elevated temperature T1, and in that steps j, 1 are executed in immediate succession.

A method, which is characterized in that the infeed of the first and second gaseous starting materials 9, 10 immediately follows the infeed of the carbon-containing reactive gas 11 into the process chamber 2, so that the carbon-containing reactive gas 11 is present in the process chamber 2 at the beginning of the deposition of the layer.

A method, which is characterized in that the carbon-containing reactive gas (11) is introduced at a total flow rate of less than 15 μmol/min, and/or in that the partial molar flow rate of the carbon-containing reactive gas (11) is less than 0.3% of the total molar flow rate.

A method, which is characterized in that steps j, k, l of claim 1 are executed with a process chamber pressure of at least 25 mbar and at most 800 mbar, of at least 35 mbar and at most 75 mbar, or of at least 35 mbar and at most 145 mbar.

All disclosed features are (individually, but also in combination with each other) essential to the invention. The disclosure of the application hereby also includes the disclosure content of the associated/attached priority documents (copy of the previous application) in full, also for the purpose of including features of these documents in claims of the present application. The subsidiary claims, even without the features of a referenced claim, characterize with their features independent inventive developments of the prior art, in particular in order to make divisional applications on the basis of these claims. The invention specified in each claim can in addition have one or a plurality of the features in the above description, in particular those provided with reference numerals, and/or specified in the list of reference numerals. The invention also relates to configurational forms in which individual features cited in the above description are not implemented, in particular insofar as they are recognizably dispensable for the intended use in question, or can be replaced by other technically equivalent means.

List of reference symbols

| | |
|---|---|
| 1 | Gas inlet element |
| 2 | Process chamber |
| 3 | Heating device |
| 4 | Susceptor |
| 5 | Gas outlet element |
| 6 | Substrate |
| 7 | CVD reactor |
| 8 | Cleaning gas source |
| 9 | Process gas source III |
| 10 | Process gas source V |
| 11 | Gas source for carbon-containing gas |
| 12 | Gas containing residues |
| 13 | Inert gas source |
| 15 | Gas supply system |
| 16 | Gas cleaning system |
| 17 | Control unit |
| R | CVD reactor |
| TR | Cleaning temperature |
| T1 | First temperature |
| T2 | Second temperature |
| T3 | Third temperature |

1. A method for depositing a layer comprising elements of main groups III and V on a substrate (6) having a silicon (Si) surface, the method comprising:
a. providing a chemical vapor deposition (CVD) reactor with a gas inlet element (1) for an injection of reactive gases into a process chamber (2) of the CVD reactor, which has a heating device (3) for heating a susceptor (4), and a gas outlet element (5) for removing decomposition products of the reactive gases from the process chamber (2);
b. providing a cleaning gas (8), which is configured to chemically react at a cleaning temperature with metal-containing residues, on surfaces of the process chamber (2) to form a gas (12) containing the metal-containing residues;
c. providing a carbon-containing reactive gas (11) that does not contain any metal;
d. providing a first gaseous starting material (9), which contains an element of main group III, and a second gaseous starting material (10), which contains an element of main group V;
e. heating the surfaces of the process chamber (2) to a cleaning temperature;
f. injecting the cleaning gas (8) into the process chamber (2), and removing the metal-containing residues through the gas outlet element (5) by the formation of the gas (12) containing the metal-containing residues;
g. purging the process chamber (2) with an inert gas (13);
h. loading the susceptor (4) with at least one substrate (6) made of silicon;
i. heating the substrate (6) up to a first temperature;
j. injecting the carbon-containing reactive gas (11) into the process chamber (2), and executing a chemical reaction of the carbon-containing gas (11) with the Si surface of the substrate (6) to form an SiC surface on the substrate (6);
k. heating the substrate (6) up to a second temperature;
l. depositing a III-V layer on the SiC surface by the injection of the first and second gaseous starting materials (9, 10) into the process chamber (2),
whereby all steps are executed in succession in the process chamber (2), and the steps j, k and l are executed in immediate succession.

2. The method of claim 1, further comprising before the production of the SiC surface in the step j, feeding hydrogen into a first chamber, and heating the first chamber to a third temperature, wherein the first chamber is either the process chamber (2) in which the substrate (6) is located, or is a different chamber.

3. The method of claim 1,
wherein the first reactive starting material (9) is an organometallic compound, or aluminum compound, and
wherein the second reactive starting material (10) is a hydride.

4. The method of claim 1, wherein the carbon-containing reactive gas (11) is a hydrocarbon.

5. The method of claim 1, wherein the cleaning gas (8) contains ammonia or a halogen, and the cleaning temperature lies between 1,000° C. and 1,300° C.

6. The method of claim 1, wherein the SiC surface is produced at the first temperature between 950° C. and 1,050° C., and the injection of the carbon-containing reactive gas continues until the Si surface of the substrate is completely saturated with SiC.

7. The method of claim 1, wherein the deposition of the III-V layer takes place between 1,000° C. and 1,100° C.

8. The method of claim 1, wherein the second temperature is equal to the first temperature, and the steps j and l are executed in immediate succession.

9. The method of claim 1, wherein the injection of the first and second gaseous starting materials (9, 10) immediately follows the injection of the carbon-containing reactive gas (11) into the process chamber (2), such that the carbon-containing reactive gas (11) remains in the process chamber (2) at a beginning of the deposition of the III-V layer.

10. The method of claim 1, wherein the carbon-containing reactive gas (11) is injected with a total molar flow rate of less than 15 mmol/min.

11. The method of claim 10, wherein a partial molar flow rate of the carbon-containing reactive gas (11) is less than 0.3% of the total molar flow rate.

12. The method of claim 1, wherein the steps j, k and l are executed with a pressure of at least 25 mbar and at most 800 mbar in the process chamber (2).

13. (canceled)

14. The method of claim 1, wherein a duration of the injection of the carbon-containing reactive gas is at least 2 seconds.
